(19) United States
(12) Patent Application Publication
(10) Pub. No.: US 2022/0317580 A1
(43) Pub. Date: Oct. 6, 2022

(54) HYDROPHOBIC MEMBRANE STRUCTURES, HYDROPHOBIC MEMBRANE STRUCTURE DETECTION METHODS, HYDROPHOBIC MEMBRANE STRUCTURE DETECTION SYSTEMS, AND WAFER CARRIERS

(71) Applicant: CHANGXIN MEMORY TECHNOLOGIES, INC., Hefei, Anhui (CN)

(72) Inventor: ChengKai HO, Hefei (CN)

(73) Assignee: CHANGXIN MEMORY TECHNOLOGIES, INC., Hefei, Anhui (CN)

(21) Appl. No.: 17/310,531

(22) PCT Filed: Feb. 8, 2021
(86) PCT No.: PCT/CN2021/076096

§ 371 Date: Aug. 7, 2021

(30) Foreign Application Priority Data
Feb. 20, 2020 (CN) 202010106044.8

(51) Int. Cl. G03F 7/20; G01N 21/78

(52) U.S. Cl. CPC G03F 7/70916; G01N 21/78; G03F 7/7095; G03F 7/70816; G03F 7/7085; G03F 7/70341

(57) ABSTRACT

A hydrophobic membrane structure includes: a color-changing layer, and a hydrophobic layer covering the surface of the color-changing layer. The color of an area of the color-changing layer in contact with the liquid changes to form a color-changing area, when the color-changing layer comes into contact with liquid.

### CROSS-REFERENCE TO RELATED APPLICATIONS

The present application claims priority to Chinese Patent Application No. 202010106044.8, entitled “Hydrophobic membrane structures, hydrophobic membrane structure detection methods, hydrophobic membrane structure detection systems, and wafer carriers”, filed on Feb. 20, 2020, which is incorporated herein by reference in its entirety.

### TECHNICAL FIELD

The present application relates to the field of semiconductors, and in particular, to a hydrophobic membrane structure, a hydrophobic membrane structure detection method, a hydrophobic membrane structure detection system, and a wafer carrier.

### BACKGROUND

In the technical field of semiconductors, especially in the wafer manufacturing process, high cleanliness of the wafer carrier is required. Therefore, at present, the common method is to install a hydrophobic membrane structure on the periphery of the wafer carrier and on other gaps with joint structures to prevent the contamination of the wafer carrier so as to improve the yield of wafers. In some situations, regular PM (Preventive maintenance) visual inspection is required to detect whether the hydrophobic membrane structure is damaged.

However, in the above situations, the damage of the hydrophobic membrane structure may be found only when the product or device goes wrong. The contamination of the wafer carrier may occur since it is unable to know the damage of the hydrophobic membrane structure in time, which affects the yield of wafers.

### SUMMARY

The purpose of the embodiments of the present application is to provide a hydrophobic membrane structure, a hydrophobic membrane structure detection method, a hydrophobic membrane structure detection system, and a wafer carrier, by which, when the hydrophobic membrane structure is broken, the color of the hydrophobic membrane structure changes, so as to solve the problem that the damage of the hydrophobic membrane structure may be found only when the product or device goes wrong.

In order to solve the above technical problem, an embodiment of the present application provides a hydrophobic membrane structure, comprising: a color-changing layer and a hydrophobic layer covering the surface of the color-changing layer; when the color-changing layer comes into contact with liquid, the color of an area of the color-changing layer in contact with the liquid changes to form a color-changing area. In this embodiment, by covering the hydrophobic layer on the surface of the color-changing layer, when the hydrophobic layer is broken, the liquid flows into the color-changing layer through the broken area, and the color of the color-changing layer changes due to its contact with the liquid. Therefore, during the detection of the hydrophobic membrane structure, whether the hydrophobic membrane structure is damaged or not is detected by the change in color, so as to replace the hydrophobic membrane structure in time if it is damaged. The problem that the damage of the hydrophobic membrane structure may be found only when the product or device goes wrong is solved.

In addition, the material for the color-changing layer comprises a temperature-sensitive color-changing material. The temperature of the color-changing layer changes when the color-changing layer comes into contact with the liquid, so that the color of the temperature-sensitive color-changing material changes.

In addition, the color-changing layer contains a plurality of color-changing particles that are on a same plane and are evenly distributed in the color-changing layer, and the color-changing particles contain the temperature-sensitive color-changing material. By providing a plurality of temperature-sensitive color-changing particles in the color-changing layer, when the color-changing layer comes into contact with water, the temperature of the temperature-sensitive color-changing particles changes to form a color-changing area.

In addition, the color-changing particles are color-changing capsules, each color-changing capsule comprising a core and a shell surrounding the core, the core being made of the temperature-sensitive color-changing material. By fixing the temperature-sensitive color-changing material in the color-changing capsule, the temperature-sensitive color-changing material in the color-changing particles is prevented from diffusing in the color-changing layer, so as to avoid affecting the uniformity of the color-changing particles.

In addition, the distance between the color-changing particles and the surface of the color-changing layer close to the hydrophobic layer is less than 0.1 mm. When the liquid reaches the color-changing layer through the broken area, the temperature-sensitive effect of the color-changing particles is better.

In addition, the color-changing particles are elliptic.

In addition, the diameter of the color-changing particles is less than 5 μm, the density of the color-changing particles is greater than 95%, and the thickness of the color-changing layer is 10 μm.

In addition, the hydrophobic membrane structure further comprises an adhesive layer; and the adhesive layer is located on the surface of the color-changing layer away from the hydrophobic layer. By providing the adhesive layer, the hydrophobic membrane structure can be torn off when the hydrophobic layer is damaged, so that the entire hydrophobic membrane structure can be easily replaced.

Another embodiment of the present application further provides a wafer carrier, comprising the hydrophobic membrane structure described above, wherein the bearing surface of the carrier has a bearing area and a first peripheral area surrounding the bearing area, the hydrophobic membrane structure is located at least on the bearing surface in the first peripheral area, and the color-changing layer is located between the bearing surface and the hydrophobic layer. By providing the hydrophobic membrane structure on the wafer carrier, it is easier to detect the color-changing area when the hydrophobic membrane structure is damaged, which facilitates timely replacement of the hydrophobic membrane structure and solves the problem that the damage of the hydrophobic membrane structure may be found only when the product or device goes wrong, thereby avoiding the contamination of the wafer carrier due to the damage of the hydrophobic membrane structure, and avoiding affecting the wafer manufacturing yield.

In addition, the bearing surface of the carrier further comprises a hollow area and a second peripheral area surrounding the hollow area, the hydrophobic membrane structure is also located on the bearing surface in the second peripheral area, and the color-changing layer is located between the bearing surface and the hydrophobic layer.

Yet another embodiment of the present application further provides a hydrophobic membrane structure detection method, which is applied to the hydrophobic membrane structure described above, comprising: detecting whether the hydrophobic membrane structure has a color-changing area, and determining whether the hydrophobic membrane structure is damaged based on the result of detection. Due to the characteristics of the hydrophobic membrane structure, when the hydrophobic layer is damaged, the color of an area of the color-changing layer in contact with the liquid changes to form a color-changing area. By detecting whether the hydrophobic membrane structure has a color-changing area, it can be determined whether the hydrophobic membrane structure is damaged. The condition of the hydrophobic membrane structure can be determined in time. The problem that the damage of the hydrophobic membrane structure may be found only when the product or device goes wrong is solved. Therefore, the cleanliness during the wafer manufacturing process is improved and the wafer manufacturing yield is improved.

In addition, the detecting whether the hydrophobic membrane structure has a color-changing area comprises: determining the position of the color-changing area when the hydrophobic membrane structure has a color-changing area, and detecting whether the hydrophobic layer in the color-changing area is damaged.

Still another embodiment of the present application further provides a hydrophobic membrane structure detection system, which is applied to the hydrophobic membrane structure described above, comprising: a first detection device, configured to detect whether the hydrophobic membrane structure has a color-changing area. The hydrophobic membrane structure detection system detects whether the hydrophobic membrane structure has a color-changing area, so as to determine whether the hydrophobic membrane structure is damaged. The condition of the hydrophobic membrane structure can be determined in time. The problem that the damage of the hydrophobic membrane structure may be found only when the product or device goes wrong is solved. Therefore, the cleanliness during the wafer manufacturing process is improved and the wafer manufacturing yield is improved.

In addition, the hydrophobic membrane structure detection system further comprises: a second detection device, configured to determine the position of the color-changing area when the hydrophobic membrane structure has a color-changing area, and determine whether the hydrophobic membrane structure in the color-changing area is damaged.

### BRIEF DESCRIPTION OF THE DRAWINGS

One or more embodiments will be exemplified by pictures in the corresponding drawings. These exemplified descriptions do not constitute any limitation to the embodiments. Elements with the same reference numerals in the drawings are represented as similar. Unless otherwise stated, the drawings are not necessarily drawn to scale.

FIG. 1 is a schematic structure diagram of a hydrophobic membrane structure according to an embodiment of the present application;

FIG. 2 is an exploded structure diagram of a hydrophobic membrane structure according to an embodiment of the present application;

FIG. 3 is a schematic structure diagram of a wafer carrier according to another embodiment of the present application;

FIG. 4 is a schematic structure diagram of a color-changing layer in a wafer carrier according to another embodiment of the present application; and

FIG. 5 is a schematic structure diagram of a detection device and a hydrophobic membrane structure according to yet another embodiment of the present application.

### DETAILED DESCRIPTION

To make the objectives, technical solutions and advantages of the embodiments of the present application clearer, the implementations of the present application will be further described below in detail with reference to the accompanying drawings. However, it may be understood by a person of ordinary skill in the art that, in the embodiments of the present application, many technical details are provided for the better understanding of the present application. However, the technical solutions sought to be protected by the present application can be implemented, even without these technical details and various changes and modifications based on the following embodiments.

In the immersion lithography process, liquid is filled between the projection lens of the lithography machine and the wafer carrier, to obtain a smaller exposure size. The liquid on the projection lens will move as the lens moves. When the liquid moves to the edge of the wafer carrier or to the gaps in other gap structures with join structures, it is easy to cause contamination of the projection lens, which in turn affects the exposure pattern on the wafer and thus the yield of products. Therefore, it is necessary to provide a hydrophobic membrane structure on the periphery of the wafer carrier and other gaps with join structures to avoid the contamination of the wafer carrier, which affects the product manufacturing yield.

It can be known from the background that, at present, the damage of the hydrophobic membrane structure may be found only when the product or device goes wrong. The damage of the hydrophobic membrane structure cannot be found in time.

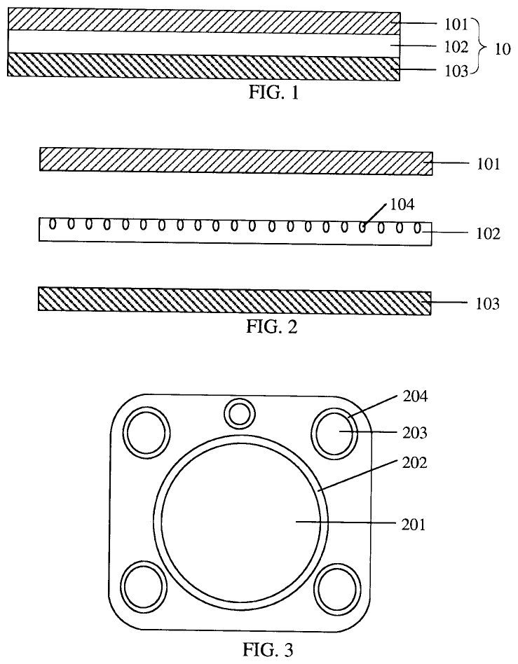

In order to solve the above problem, an embodiment of the present application provides a hydrophobic membrane structure. As shown in FIG. 1, the hydrophobic membrane structure 10 comprises: a color-changing layer 102 and a hydrophobic layer 101 covering the surface of the color-changing layer 102.

The hydrophobic membrane structure 10 mainly functions to prevent the liquid from flowing to the edge of the wafer carrier and to other gaps with the join structures by dispersing the liquid on the surface of the membrane, thereby ensuring the cleanliness of the wafer carrier and improving the product manufacturing yield. Therefore, in this embodiment, in order to determine whether the hydrophobic membrane structure 10 is damaged in time and to solve the problem that the damage of the hydrophobic membrane structure 10 may be found only when the product or device goes wrong, a color-changing layer 102 is provided. The color-changing layer 102 is covered by the hydrophobic layer 101. When the hydrophobic layer 101 is broken, the liquid on the surface of the hydrophobic layer 101 reaches the color-changing layer 102 through the broken area. The color of an area of the color-changing layer 102 in contact with the liquid changes to form a color-changing area, when the color-changing layer 102 comes into contact with the liquid.

In this embodiment, the hydrophobic membrane structure 10 further comprises: an adhesive layer 103; and the adhesive layer 103 is located on the surface of the color-changing layer 102 away from the hydrophobic layer 101. By providing the adhesive layer 103, the hydrophobic membrane structure 10 can be torn off when the hydrophobic layer 101 is damaged, so that the entire hydrophobic membrane structure 10 can be easily replaced.

In this embodiment, the material for the color-changing layer 102 comprises a temperature-sensitive color-changing material. The temperature of the area of the color-changing layer 102 in contact with the liquid changes, when the liquid reaches the color-changing layer 102 through the broken area. Since the color-changing layer 102 contains the temperature-sensitive color-changing material, the color of the area of the color-changing layer 102 in contact with the liquid changes as the temperature changes, to form a color-changing area.

In this embodiment, as shown in FIG. 2, the color-changing layer 102 contains a plurality of color-changing particles 104 that are on a same plane and are evenly distributed in the color-changing layer 102, the color-changing particles 104 containing the temperature-sensitive color-changing material. By providing a plurality of color-changing particles 104 in the color-changing layer 102, the mutual influence of colors between the color-changing particles 104 can be reduced, and the color-changing area can be better determined.

In one example, the distance between the color-changing particles 104 and the surface of the color-changing layer 102 close to the hydrophobic layer 101 is less than 0.1 mm. When the liquid reaches the color-changing layer 102 through the broken area, there is a small distance between the color-changing particles 104 and the liquid, so that it is easier for the color-changing particles 104 to feel the temperature of the liquid and it is more likely for a color-changing area to be formed in the color-changing layer 102. The temperature sensitivity of the color-changing layer 102 is improved.

In one example, the color-changing particles 104 are color-changing capsules, each color-changing capsule comprising a core and a shell surrounding the core, the core being made of the temperature-sensitive color-changing material. By fixing the temperature-sensitive color-changing material in the color-changing capsules, the stability of the color-changing particles 104 is improved, and the temperature-sensitive color-changing material in the color-changing particles 104 is prevented from diffusing in the color-changing layer 102, so as to avoid affecting the uniformity of the color-changing particles 104.

In one example, the color-changing particles 104 are elliptic.

In one example, the diameter of the color-changing particles 104 is less than 5 μm, the density of the color-changing particles is greater than 95%, and the thickness of the color-changing layer 102 is 10 μm.

In this embodiment, the hydrophobic layer 101 is covered on the surface of the color-changing layer 102. When the hydrophobic layer 101 is broken, the liquid flows into the color-changing layer 102 through the broken area of the hydrophobic layer 101, and the color of the color-changing layer 102 changes due to the color-changing layer 102 comes into contact with the liquid. Therefore, during the detection, the damage of the hydrophobic membrane structure 10 can be detected by the change in color. It is convenient for timely replacement of the hydrophobic membrane structure, thereby avoiding the contamination of the wafer carrier and improving the wafer manufacturing yield.

Another embodiment of the present application relates to a wafer carrier.

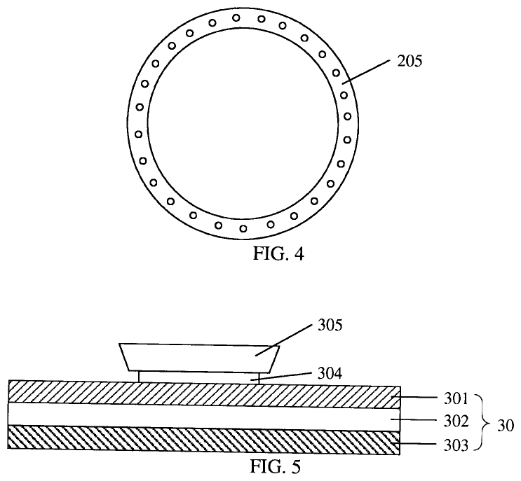

Referring to FIG. 3, the wafer carrier comprises the hydrophobic membrane structure described above. The bearing surface of the carrier has a bearing area 201 and a first peripheral area 202 surrounding the bearing area 201, and the hydrophobic membrane structure is located at least on the bearing surface in the first peripheral area 202. Referring to FIG. 4, a schematic structure diagram of a color-changing layer 205 with color-changing particles, which is disposed in the first peripheral region 202, is shown. The color-changing layer 205 is located between the bearing surface and the hydrophobic layer. In other embodiments, the hydrophobic membrane structure may be located in the bearing area 201.

In this embodiment, the bearing surface of the carrier further comprises a hollow area 203 and a second peripheral area 204 surrounding the hollow area 203. The hydrophobic membrane structure is also located on the bearing surface in the second peripheral area 204, and the color-changing layer is located between the bearing surface and the hydrophobic layer. In this embodiment, the bearing surface of the carrier comprises five sets of structures, each consisting of the hollow area 203 and the second peripheral area 204 surrounding the hollow area 203. The size and shape of each hollow area 203 are determined according to actual production requirements and will not be specifically limited in this embodiment.

In this embodiment, by providing the hydrophobic membrane structure on the wafer carrier, it is easier for the detection device to detect the color-changing area when the hydrophobic membrane structure is damaged, which facilitates timely replacement of the hydrophobic membrane structure and solves the problem that the damage of the hydrophobic membrane structure may be found only when the product or device goes wrong, thereby avoiding the contamination of the wafer carrier due to the damage of the hydrophobic membrane structure and avoiding affecting the wafer manufacturing yield.

Yet another embodiment of the present application relates to a hydrophobic membrane structure detection method, which is applied to the hydrophobic membrane structure described above.

It can be know from the forgoing description that, in the immersion lithography process, the projection lens of the lithography machine is required to expose the wafer. Referring to FIG. 5, a schematic structure diagram of a detection device and a hydrophobic membrane structure during the exposure of the wafer by the projection lens of the lithography machine is shown, comprising: a hydrophobic membrane structure 30, a liquid layer 304 and a lens 305. The hydrophobic membrane structure 30 comprises a hydrophobic layer 301, a color-changing layer 302, and an adhesive layer 303. Due to the liquid layer 304, the resolution of the wafer exposure is improved, and the obtained image is clearer. Meanwhile, because the liquid layer 304 comes into contact with the hydrophobic membrane structure 30 during the exposure, when the hydrophobic layer 301 of the hydrophobic membrane structure 30 is damaged, the liquid in the liquid layer 304 comes into contact with the color-changing layer 302 through the broken area, so that the color of the color-changing layer 302 changes.

In this embodiment, in order to detect whether the hydrophobic membrane structure 30 is damaged, firstly, the first detection device detects whether the hydrophobic membrane structure 30 has a color-changing area.

Specifically, the first detection device, i.e., a machine vision system (specifically, a camera in the machine vision system), can detect whether the hydrophobic membrane structure 30 has a color-changing area. In the immersion lithography process, before the exposure of the wafer and after the exposure of the wafer, it is necessary to sample images of the hydrophobic membrane structure 30 on the wafer carrier by the camera, and by the images obtained before or after the exposure, determine whether the hydrophobic membrane structure 30 has a color-changing area before or after the exposure, thereby improving the production yield of the immersion lithography process.

In one example, after detecting whether the hydrophobic membrane structure 30 has a color-changing area, the method comprises: determining, by a second detection device, the position of the color-changing area when the first detection device determines that the hydrophobic membrane structure 30 has a color-changing area; and then detecting, by PM visual inspection, whether the hydrophobic layer 301 in the color-changing area is damaged. In this embodiment, when the hydrophobic membrane structure 30 has a color-changing area, the machine vision system sends a signal indicating that there is a color-changing area. In order to more accurately detect whether the hydrophobic membrane structure 30 is damaged, after a color-changing area is formed on the hydrophobic membrane structure 30, the position of the color-changing area is determined, and in the color-changing area, whether the hydrophobic membrane structure is broken is detected by PM visual inspection.

Finally, it is determined whether the hydrophobic membrane structure 30 is damaged based on the result of detection.

In one example, the breaking of the hydrophobic layer 301 will cause the liquid to reach the color-changing layer 302 through the broken area. Then, the color of the color-changing layer 302 changes to form a color-changing area. Therefore, when it is detected by the machine vision system that the hydrophobic membrane structure 30 has a color-changing area, it can be determined that the hydrophobic membrane structure 30 is damaged.

In one example, the device may incorrectly determine that the hydrophobic membrane structure has a color-changing area due to abnormality. Therefore, after the hydrophobic membrane structure 30 has a color-changing area, it is necessary to further detect whether the hydrophobic membrane structure 30 is damaged. In this embodiment, it is also necessary to detect whether the color-changing area is broken by manual PM visual inspection. If the result of detection shows that the hydrophobic membrane structure 30 in the color-changing area is broken, it is determined that the hydrophobic membrane structure 30 is damaged.

In one example, after determining that the hydrophobic membrane structure 30 is damaged, the hydrophobic membrane structure 30 is replaced. Since the hydrophobic membrane structure 30 comprises the adhesive layer 303, it is convenient to replace the hydrophobic membrane structure 30.

In this embodiment, due to the characteristics of the hydrophobic membrane structure, when the hydrophobic layer is damaged, the color of the area of the color-changing layer in contact with the liquid changes to form a color-changing area. By detecting whether the hydrophobic membrane structure has a color-changing area so as to determine whether the hydrophobic layer is damaged, the condition of the hydrophobic membrane structure can be determined in time. Therefore, the cleanliness of the wafer carrier is improved and the wafer manufacturing yield is improved.

Still another embodiment of the present application relates to a hydrophobic membrane structure detection system, which is applied to the hydrophobic membrane structure described above, comprising: a first detection device, configured to detect whether the hydrophobic membrane structure has a color-changing area. By detecting, by the hydrophobic membrane structure detection system, whether the hydrophobic membrane structure has a color-changing area so as to determine whether the hydrophobic membrane structure is damaged, the condition of the hydrophobic membrane structure can be determined in time. Therefore, the cleanliness during the wafer manufacturing process is improved and the wafer manufacturing yield is improved.

It is not really surprising to discover that this embodiment is a system embodiment corresponding to the previous embodiment, and this embodiment may be implemented together with the previous embodiment. Related technical details mentioned in the previous embodiment are applicable to this embodiment and will not be repeated for simplicity. Correspondingly, related technical details mentioned in this embodiment are applicable to the previous embodiment.

In one example, the hydrophobic membrane structure detection system further includes: a second detection device, configured to determine the position of the color-changing area when the hydrophobic membrane structure has a color-changing area.

The division of the steps of the various methods above is just for clarity of description. When implemented, the steps may be combined into one step or some steps may be split and decomposed into multiple steps, as long as they include the same logical relationship, without departing from the scope of the present application. Adding insignificant modifications to the algorithm or process or introducing insignificant designs without changing the key design of the algorithm or process are within the protection scope of the present application.

It may be understood by a person of ordinary skill in the art that the above embodiments are specific embodiments for realizing the present application, and in actual applications, various changes may be made to the form and details without departing from the spirit and scope of the present application.

1. A hydrophobic membrane structure, comprising: a color-changing layer and a hydrophobic layer covering the surface of the color-changing layer; and
when the color-changing layer comes into contact with liquid, the color of an area of the color-changing layer in contact with the liquid changes to form a color-changing area.

2. The hydrophobic membrane structure according to claim 1, wherein the material for the color-changing layer comprises a temperature-sensitive color-changing material.

3. The hydrophobic membrane structure according to claim 2, wherein the color-changing layer contains a plurality of color-changing particles that are on a same plane and are evenly distributed in the color-changing layer, and the color-changing particles contain the temperature-sensitive color-changing material.

4. The hydrophobic membrane structure according to claim 3, wherein the color-changing particles are color-changing capsules, each color-changing capsule comprising a core and a shell surrounding the core, the core being made of the temperature-sensitive color-changing material.

5. The hydrophobic membrane structure according to claim 3, wherein the distance between the color-changing particles and the surface of the color-changing layer close to the hydrophobic layer is less than 0.1 mm.

6. The hydrophobic membrane structure according to claim 3, wherein the color-changing particles are elliptic.

7. The hydrophobic membrane structure according to claim 3, wherein the diameter of the color-changing particles is less than 5 μm, the density of the color-changing particles is greater than 95%, and the thickness of the color-changing layer is 10 μm.

8. The hydrophobic membrane structure according to claim 1, further comprising an adhesive layer; and
the adhesive layer is located on the surface of the color-changing layer away from the hydrophobic layer.

9. A wafer carrier, comprising the hydrophobic membrane structure according to claim 1, wherein the bearing surface of the carrier has a bearing area and a first peripheral area surrounding the bearing area, the hydrophobic membrane structure is located at least on the first peripheral area of the bearing surface, and the color-changing layer is located between the first peripheral area and the hydrophobic layer.

10. The wafer carrier according to claim 9, wherein the bearing surface of the carrier further comprises a hollow area and a second peripheral area surrounding the hollow area, the hydrophobic membrane structure is also located on the second peripheral area of the bearing surface, and the color-changing layer is located between the second peripheral area and the hydrophobic layer.

11. The wafer carrier according to claim 10, wherein the bearing surface of the carrier includes five sets of structures, each consisting of the hollow area and the second peripheral area surrounding the hollow area.

12. A hydrophobic membrane structure detection method, used for detecting the hydrophobic membrane structure according to claim 1, comprising:
detecting, by a first detection device, whether the hydrophobic membrane structure has a color-changing area, and determining whether the hydrophobic membrane structure is damaged based on the result of detection.

13. The hydrophobic membrane structure detection method according to claim 12, wherein the detecting whether the hydrophobic membrane structure has a color-changing area comprises:
determining, by a second detection device, the position of the color-changing area when the first detection device determines that the hydrophobic membrane structure has a color-changing area; and
detecting, by PM visual inspection, whether the hydrophobic layer in the color-changing area is damaged.

14. The hydrophobic membrane structure detection method according to claim 13, after the detecting, by PM visual inspection, whether the hydrophobic membrane structure is damaged, comprising:
replacing the hydrophobic membrane structure when it is determined that the hydrophobic membrane structure is damaged.

15. A hydrophobic membrane structure detection system, used for detecting the hydrophobic membrane structure according to claim 1, comprising:
a first detection device, configured to detect whether the hydrophobic membrane structure has a color-changing area.

16. The hydrophobic membrane structure detection system according to claim 15, further comprising:
a second detection device, configured to determine the position of the color-changing area when the hydrophobic membrane structure has a color-changing area.

17. A wafer carrier, comprising the hydrophobic membrane structure according to claim 2, wherein the bearing surface of the carrier has a bearing area and a first peripheral area surrounding the bearing area, the hydrophobic membrane structure is located at least on the first peripheral area of the bearing surface, and the color-changing layer is located between the first peripheral area and the hydrophobic layer.

18. A wafer carrier, comprising the hydrophobic membrane structure according to claim 3, wherein the bearing surface of the carrier has a bearing area and a first peripheral area surrounding the bearing area, the hydrophobic membrane structure is located at least on the first peripheral area of the bearing surface, and the color-changing layer is located between the first peripheral area and the hydrophobic layer.

19. A hydrophobic membrane structure detection method, used for detecting the hydrophobic membrane structure according to claim 2, the method comprising:
detecting, by a first detection device, whether the hydrophobic membrane structure has a color-changing area, and determining whether the hydrophobic membrane structure is damaged based on the result of detection.

20. A hydrophobic membrane structure detection system, used for detecting the hydrophobic membrane structure according to claim 2, the system comprising:
a first detection device, configured to detect whether the hydrophobic membrane structure has a color-changing area.
